(19) United States
(12) Patent Application Publication
(10) Pub. No.: US 2018/0226583 A1
(43) Pub. Date: Aug. 9, 2018

(54) CHARGE TRANSFER SALT, ELECTRONIC DEVICE AND METHOD OF FORMING THE SAME

(71) Applicants: Cambridge Display Technology Limited, Cambridgeshire (GB); Sumitomo Chemical Company Limited, Tokyo (JP)

(72) Inventors: Thomas Kugler, Godmanchester (GB); Florence Bourcet, Godmanchester (GB); Sheena Zuberi, Godmanchester (GB); Tania Zuberi, Godmanchester (GB)

(73) Assignees: Cambridge Display Technology Limited, Cambridgeshire (GB); Sumitomo Chemical Company Limited, Tokyo (JP)

(21) Appl. No.: 15/749,248

(22) PCT Filed: Jul. 29, 2016
(86) PCT No.: PCT/GB2016/052347

§ 371 Date: Jan. 31, 2018

(30) Foreign Application Priority Data
Jul. 31, 2015 (GB) 1513608.8
Dec. 18, 2015 (GB) 1522439.7
Feb. 19, 2016 (GB) 1602925.8

(51) Int. Cl. H01L 51/00; C08G 61/10

(52) U.S. Cl. CPC H01L 51/0039; H01L 51/5092; C08G 61/10; H01L 51/0043

(57) ABSTRACT

Charge Transfer Salt, Electronic Device and Method of Forming the Same A charge-transfer salt formed from a material comprising a unit of formula (I) and an n-dopant: wherein Ar¹ is an arylene group; R¹ is a substituent comprising at least one cyano group; n is at least 1; R² is a substituent; and m is 0 or a positive integer. The material may be a polymer. The charge-transfer salt may be used as a layer of an organic electronic device.

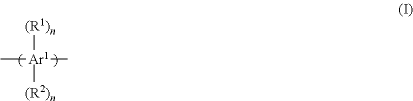

### FIELD OF THE INVENTION

The invention relates to n-doped materials, methods of forming n-doped materials and electronic devices containing n-doped materials.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An organic light-emitting device has a substrate carrying an anode, a cathode and an organic light-emitting layer containing a light-emitting material between the anode and cathode.

In operation, holes are injected into the device through the anode and electrons are injected through the cathode. Holes in the highest occupied molecular orbital (HOMO) and electrons in the lowest unoccupied molecular orbital (LUMO) of the light-emitting material combine to form an exciton that releases its energy as light.

Cathodes include a single layer of metal such as aluminium, a bilayer of calcium and aluminium as disclosed in WO 98/10621; and a bilayer of a layer of an alkali or alkali earth compound and a layer of aluminium as disclosed in L. S. Hung, C. W. Tang, and M. G. Mason, Appl. Phys. Lett. 70, 152 (1997).

An electron-transporting or electron-injecting layer may be provided between the cathode and the light-emitting layer.

Bao et al, “Use of a 1H-Benzoimidazole Derivative as an n-Type Dopant and To Enable Air-Stable Solution-Processed n-Channel Organic Thin-Film Transistors” J. Am. Chem. Soc. 2010, 132, 8852-8853 discloses doping of [6,6]-phenyl C₆₁ butyric acid methyl ester (PCBM) by mixing (4-(1,3-dimethyl-2,3-dihydro-1H-benzoimidazol-2-yl)phenyl)dimethylamine (N-DMBI) with PCBM and activating the N-DMBI by heating.

US 2014/070178 discloses an OLED having a cathode disposed on a substrate and an electron-transporting layer formed by thermal treatment of an electron-transporting material and N-DMBI. It is disclosed that a radical formed on thermal treatment of N-DMBI may be a n-dopant.

U.S. Pat. No. 8,920,944 discloses n-dopant precursors for doping organic semiconductive materials.

Naab et al, “Mechanistic Study on the Solution-Phase n-Doping of 1,3-Dimethyl-2-aryl-2,3-dihydro-1H-benzoimidazole Derivatives”, J. Am. Chem. Soc. 2013, 135, 15018-15025 discloses that n-doping may occur by a hydride transfer pathway or an electron transfer pathway.

US 2006/251922 discloses an OLED having an electron-injecting layer containing an organic host material and a dopant capable of reducing the organic host material.

It is an object of the invention to provide organic electronic devices comprising n-doped layers having improved performance.

It is a further object of the invention to provide materials capable of undergoing efficient n-doping.

### SUMMARY OF THE INVENTION

In a first aspect the invention provides a charge-transfer salt formed from a material comprising a unit of formula (I) and an n-dopant:

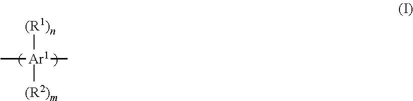

wherein Ar¹ is an arylene group; R¹ is a substituent comprising at least one cyano group; n is at least 1; R² is a substituent; and m is 0 or a positive integer.

In a second aspect the invention provides a method of forming a charge-transfer salt according to the first aspect, the method comprising the step of activating a composition comprising the material comprising a unit of formula (I) and the n-dopant to cause the n-dopant to dope the material comprising a unit of formula (I).

In a third aspect the invention provides an organic electronic device comprising a layer comprising a charge-transfer salt according to the first aspect.

In a fourth aspect the invention provides a composition comprising a material comprising a unit of formula (I) and an n-dopant:

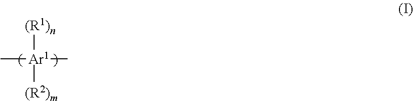

wherein A¹ is an arylene group; R¹ is a substituent comprising at least one cyano group; n is at least 1; R² is a substituent; and m is 0 or a positive integer.

In a fifth aspect the invention provides a formulation comprising a composition according to the fourth aspect and at least one solvent.

In a sixth aspect the invention provides a method of forming a layer of an organic electronic device comprising a charge-transfer salt according to the first aspect, the method comprising the step of depositing a formulation according to the fifth aspect onto a surface; evaporating the at least one solvent; and activating the n-dopant.

### DESCRIPTION OF THE DRAWINGS

The invention will now be described in more detail with reference to the drawings in which:

FIG. 1 illustrates schematically an OLED according to an embodiment of the invention;

FIG. 2 is a graph of current density vs. voltage for electron-only devices comprising charge-transfer salts according to embodiments of the invention and for a comparative device; and

FIG. 3 is a graph of current density vs. voltage for blue fluorescent OLEDs comprising charge-transfer salts according to embodiments of the invention.

### DETAILED DESCRIPTION OF THE INVENTION

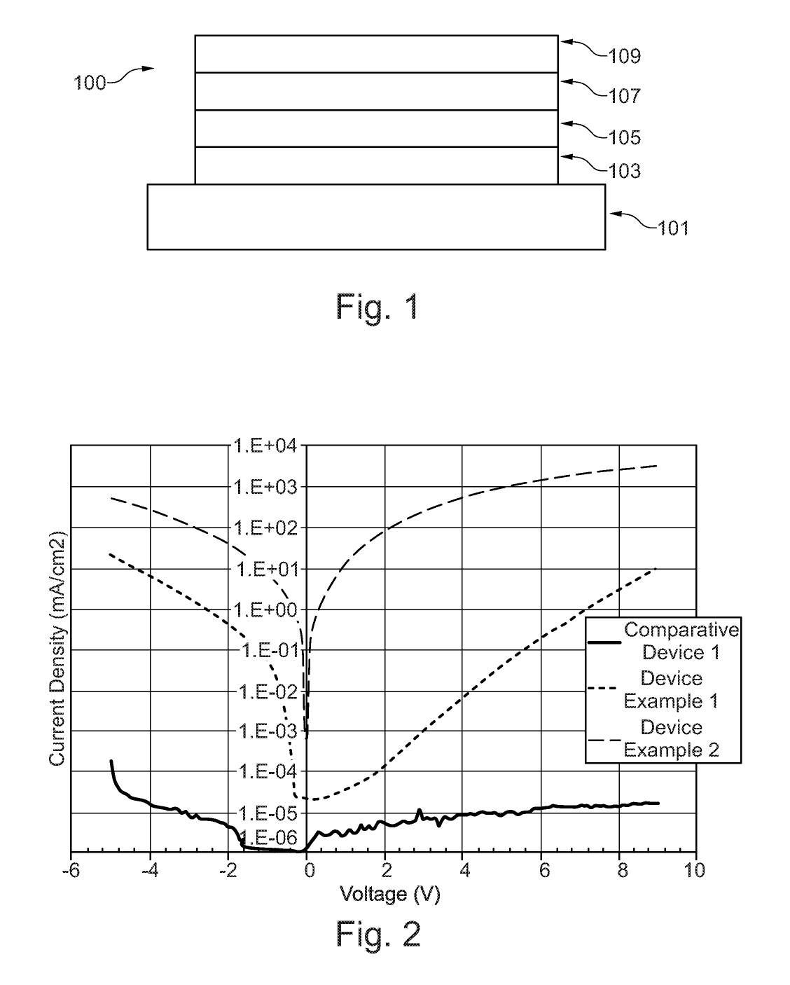

FIG. 1, which is not drawn to any scale, illustrates an OLED 100 according to an embodiment of the invention supported on a substrate 101, for example a glass or plastic substrate. The OLED 100 comprises an anode 103, a light-emitting layer 105, an electron-injecting layer 107 and a cathode 109.

The anode 103 may be single layer of conductive material or may be formed from two or more conductive layers. Anode 103 may be a transparent anode, for example a layer of indium-tin oxide. A transparent anode 103 and a transparent substrate 101 may be used such that light is emitted through the substrate. The anode may be opaque, in which case the substrate 101 may be opaque or transparent, and light may be emitted through a transparent cathode 109.

Light-emitting layer 105 contains at least one light-emitting material. Light-emitting material 105 may consist of a single light-emitting material or may be a mixture of more than one material, optionally a host doped with one or more light-emitting dopants. Light-emitting layer 105 may contain at least one light-emitting material that emits phosphorescent light when the device is in operation, or at least one light-emitting material that emits fluorescent light when the device is in operation. Light-emitting layer 105 may contain at least one phosphorescent light-emitting material and at least one fluorescent light-emitting material.

Electron-injecting layer 107 comprises or consists of a charge-transfer salt formed from an acceptor material comprising a unit of formula (I) doped by an n-dopant. The present inventors have found that repeat units of formula (I) can be n-doped efficiently.

The charge transfer salt may be formed from a mixture of the acceptor material and a separate n-dopant mixed with the acceptor material, or the n-dopant may be covalently bound to the acceptor material.

The acceptor material is preferably a polymer comprising repeat units of formula (I), in which case the polymer may comprise the repeat units of formula (I) and a co-repeat unit substituted with the n-dopant.

In addition to the charge-transfer salt, electron-injection layer 107 may comprise undoped acceptor material comprising a unit of formula (I) and/or n-dopant that has not doped the polymer.

Cathode 109 is formed of at least one layer, optionally two or more layers, for injection of electrons into the device.

Preferably, the electron-injecting layer 107 is adjacent to organic light-emitting layer 105.

Preferably, the acceptor material has a LUMO that is no more than about 1 eV, optionally less than 0.5 eV or 0.2 eV, deeper (i.e. further from vacuum) than a LUMO of a material of the light-emitting layer, which may be a LUMO of a light-emitting material or a LUMO of a host material if the light-emitting layer comprises a mixture of a host material and a light-emitting material. Optionally, the doped material has a work function that is about the same as a LUMO of a material of the light-emitting layer. Optionally, the material comprising a unit of formula (I) has a LUMO of less (i.e. closer to vacuum) than 3.0 eV from vacuum level, optionally around 2.1 to 2.8 eV from vacuum level. Preferably, the material comprising a unit of formula (I) has a LUMO level of no more than 2.7 eV or no more than 2.6 eV from vacuum level. Preferably, the material comprising a unit of formula (I) has a LUMO level of more than 2.2 eV or 2.3 eV from vacuum level.

HOMO and LUMO levels as described herein are as measured by square wave voltammetry.

Preferably, the cathode 109 is in contact with the electron-injecting layer 107.

The OLED 100 may be a display, optionally a full-colour display wherein the light-emitting layer 105 comprises pixels comprising red, green and blue subpixels.

The OLED 100 may be a white-emitting OLED. White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K. A white-emitting OLED may contain a plurality of light-emitting materials, preferably red, green and blue light-emitting materials, more preferably red, green and blue phosphorescent light-emitting materials, that combine to produce white light. The light-emitting materials may all be provided in light-emitting layer 105, or one or more additional light-emitting layers may be provided.

A red light-emitting material may have a photoluminescence spectrum with a peak in the range of about more than 550 up to about 700 nm, optionally in the range of about more than 560 nm or more than 580 nm up to about 630 nm or 650 nm.

A green light-emitting material may have a photoluminescence spectrum with a peak in the range of about more than 490 nm up to about 560 nm, optionally from about 500 nm, 510 nm or 520 nm up to about 560 nm.

A blue light-emitting material may have a photoluminescence spectrum with a peak in the range of up to about 490 nm, optionally about 450-490 nm.

Photoluminescence spectra described herein are as measured by casting 5 wt % of the material in a polystyrene film onto a quartz substrate and measuring in a nitrogen environment using apparatus C9920-02 supplied by Hamamatsu.

The OLED 100 may contain one or more further layers between the anode 103 and the cathode 109, for example one or more charge-transporting, charge-blocking or charge-injecting layers. Preferably, the device comprises a hole-injection layer comprising a conducting material between the anode and the light emitting layer 105. Preferably, the device comprises a hole-transporting layer comprising a semiconducting hole-transporting material between the anode 103 and the light emitting layer 105.

The n-dopant may spontaneously dope the material comprising a unit of formula (I) to form the charge-transfer salt, or n-doping may occur upon activation, for example heat or irradiation of the n-dopant and acceptor. If n-doping occurs upon activation then the activation may occur before or after formation of the cathode.

The electron-injecting layer may comprise or consist of the charge-transfer salt.

In forming the electron-injecting layer, the material comprising a unit of formula (I) and n-dopant may be deposited in air.

In forming the electron-injecting layer, the material comprising a unit of formula (I) and the n-dopant (which may be covalently bound to the material comprising a unit of formula (I), such as a substituent of a co-repeat unit of a polymer comprising repeat units of formula (I), or may be a separate material mixed with the material comprising a unit of formula (I)) may be deposited from a solution in a solvent or solvent mixture. The solvent or solvent mixture may be selected to prevent dissolution of the underlying layer, such as an underlying organic light-emitting layer 105, or the underlying layer may be crosslinked.

The material comprising a unit of formula (I) may be a non-polymeric material containing a single unit of formula (I); an oligomer comprising a plurality of units of formula (I), optionally 2-10 units of formula (I), or a polymer comprising repeat units of formula (I). The material is preferably a polymer, more preferably a conjugated polymer comprising repeat units of formula (I) conjugated to one another and/or conjugated to aromatic or heteroaromatic groups of co-repeat units adjacent to the repeat units of formula (I).

A non-polymeric material may have formula (X):

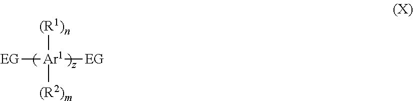

wherein EG in each occurrence is an end group, optionally a group selected from C₆₋₂₀ aryl that may be unsubstituted or substituted with one or more substituents and z is 1-10. Exemplary C₆₋₂₀ aryl groups are phenyl, naphthyl, anthryl, phenanthrene and fluorene, each of which may be unsubstituted or substituted with one or more substituents, optionally one or more C₁₋₂₀ hydrocarbyl groups.

Ar¹ of formula (I) is preferably a C₆₋₂₀ arylene group, preferably an arylene group selected from phenylene, naphthylene, fluorene, anthracene, pyrene, perylene and phenanthrene.

Ar¹ of formula (I) is substituted with at least one group R¹ comprising cyano. Ar¹ may be substituted with only one group R¹ or may be substituted two or more groups R¹.

The one or more substituents R¹ may be the only substituents of Ar¹ or Ar¹ may be substituted with one or more substituents R² wherein each R² is a substituent other than a group comprising cyano.

The unit of formula (I) is preferably selected from units of formulae (Ia)-(Ig):

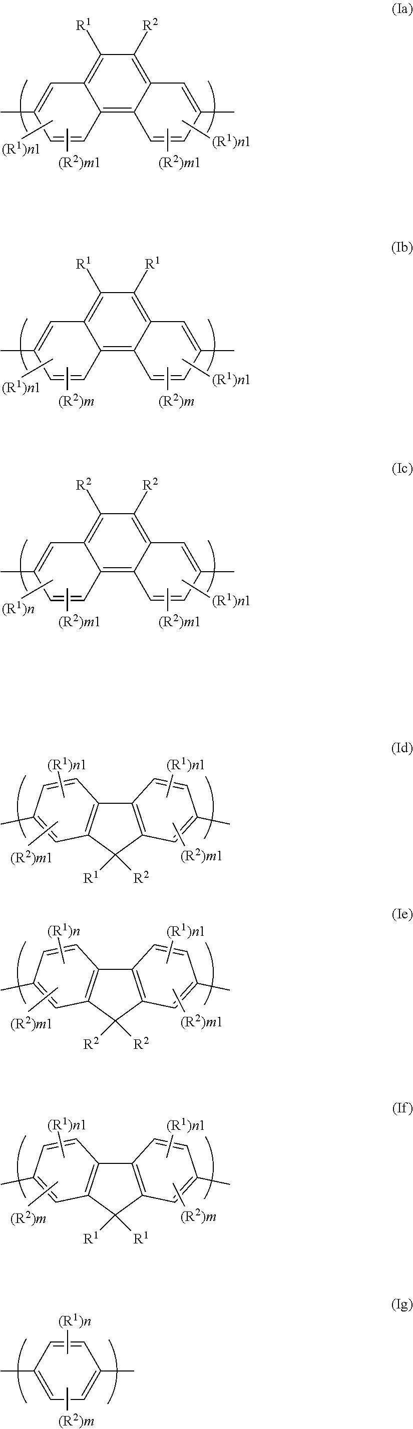

wherein n is at least 1; m independently in each occurrence is 0 or a positive integer; n1 independently in each occurrence is 0 or a positive integer; and ml independently in each occurrence is 0 or a positive integer.

Each R¹ independently may be cyano or may be a group comprising one or more cyano groups.

R¹ may be a group of formula (II):

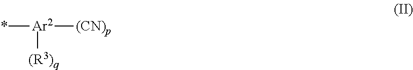

wherein Ar² is any aryl or heteroaryl group; p is at least 1; R³ is a substituent; and q is 0 or a positive integer.

Ar² is preferably phenyl.

p is preferably 1.

In the case where q is a positive integer, optionally 1, 2, 3 or 4, the group R³ may be selected from alkyl, optionally C₁₋₂₀ alkyl, wherein one or more non-adjacent C atoms may be replaced with O, S, C═O or —COO and one or more H atoms may be replaced with F.

If present, R² independently in each occurrence may be selected from the group consisting of:
C₁₋₂₀ alkyl wherein one or more non-adjacent, non-terminal C atoms may be replaced with O;
an ionic group, optionally a carboxylate group; and
a group of formula —(Ar³)ᵣ wherein Ar³ in each occurrence is independently a C₆₋₂₀ aryl or 5-20 membered heteroaryl group that is unsubstituted or substituted with one or more substituents and r is at least 1, optionally 1, 2 or 3.

“non-terminal C atom” of an alkyl group as used herein means a C atom other than the methyl group at the end of an n-alkyl group or the methyl groups at the ends of a branched alkyl chain.

Ar³ is preferably phenyl.

Substituents of Ar³, if present, may independently be selected from substituents R⁴ wherein R⁴ in each occurrence is independently C₁₋₂₀ alkyl wherein one or more non-adjacent, non-terminal C atoms may be replaced with O; and an ionic substituent, optionally a carboxylate group.

Ionic substituents as described anywhere herein may be cationic or anionic. Exemplary anionic or cationic substituents have formula (VIII):

-(Sp¹)ᵤ-(A)ᵥ (VIII)

wherein Sp¹ is a spacer group; A is an anion or cation; u is 0 or 1; v is 1 if u is 0; and v is at least 1, preferably 1, if u is 1.

Optionally, Sp¹ is selected from:

C₁₋₂₀ alkylene or phenylene-C₁₋₂₀ alkylene wherein one or more non-adjacent C atoms may be replace with O, S or C═O;
a C₆₋₂₀ arylene or 5-20 membered heteroarylene, more preferably phenylene, which may be unsubstituted or substituted with one or more C₁₋₂₀ alkyl groups wherein one or more non-adjacent, non-terminal C atoms of the C₁₋₂₀ alkyl groups may be replaced with O, S, C═O or COO; and
a C₆₋₂₀ arylene alkylene spacer group or an alkylene-C₆₋₂₀ arylene spacer group wherein C₁₋₂₀ alkylene and C₆₋₂₀ arylene are as described above and wherein C atoms of alkylene groups may be replaced with O, S or C═O.

An exemplary anion A is —COO⁻.

An exemplary cation A is —NR⁵₃⁺ wherein R⁵ in each occurrence is H or C₁₋₁₂ hydrocarbyl. Preferably, each R⁵ is a C₁₋₁₂ hydrocarbyl.

A material comprising a unit of formula (I) substituted with one or more ionic groups A comprise one or more counterions B to balance the charge of the anions or cations A.

A of formula (VIII) and B may have the same valency, with a counterion B balancing the charge of each A of formula (VIII).

Anion or cation A may be monovalent or polyvalent. Preferably, A and B are each monovalent.

In another embodiment, the material comprising a unit of formula (I) may be substituted with a plurality of anions or cations A wherein the charge of two or more anions or cations A is balanced by a single counterion B.

Cation B is optionally a metal cation, optionally Li⁺, Na⁺, K⁺, Cs⁺, preferably Cs⁺, or an organic cation, optionally ammonium, such as tetraalkylammonium, ethylmethyl imidazolium or pyridinium.

Anion B is optionally halide, sulfonate group optionally mesylate or tosylate, hydroxide, carboxylate, sulfate, phosphate, phosphinate, phosphonate or borate.

R², R³ and R⁴ are independently in each occurrence selected from the group consisting of:

C₁₋₄₀ hydrocarbyl groups, preferably C₁₋₂₀ alkyl groups, unsubstituted phenyl and phenyl substituted with one or more C₁₋₁₂ alkyl groups;
ionic substituents, optionally substituents of formula (VIII), optionally a carboxylate group;
a mono- or poly-ether group, optionally a substituent comprising or consisting of a group of formula —(OCH₂CH₂)_{w}—R¹² wherein w is at least 1, optionally an integer from 1 to 10 and R¹² is a C₁₋₅ alkyl group, preferably methyl;
and groups of formula —COOR¹³ wherein R¹³ is a C₁₋₅ alkyl group.

Substituents R², R³ and/or R⁴ may be selected according to a desired solubility of the material.

Preferred substituents R², R³ and/or R⁴ for solubility in non-polar solvents are C₁₋₄₀ hydrocarbyl groups, preferably C₁₋₂₀ alkyl groups and phenyl substituted with one or more C₁₋₁₂ alkyl groups.

Preferably, substituents R², R³ and/or R⁴ for solubility in polar solvents are selected from: ionic groups; mono- or poly-ether groups; and groups of formula —COOR¹⁰.

A polymer comprising ester substituents may be converted to a polymer comprising a group of formula —COO⁻M⁺. The conversion may be as described in WO 2012/133229, the contents of which are incorporated herein by reference.

A unit of formula (I) may be selected from:

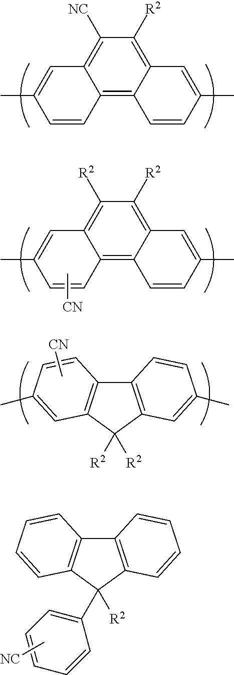

Exemplary units of formula (I) are:

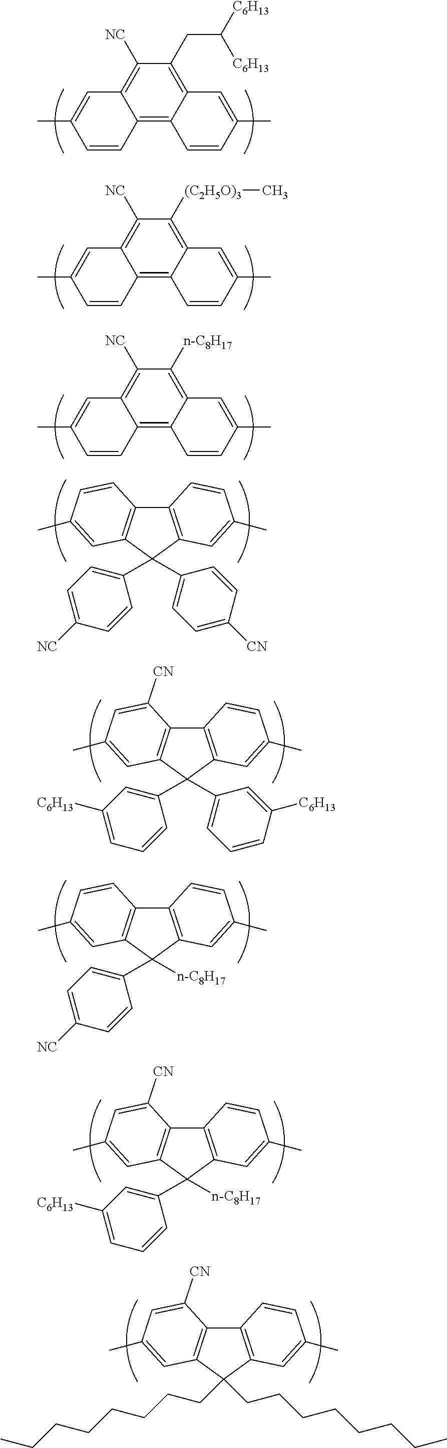

In the case where the acceptor material is a polymer comprising repeat units of formula (I), all of the repeat units of the polymer backbone may be repeat units of formula (I).

The polymer may comprise only one repeat unit of formula (I) or may comprise two or more different repeat units of formula (I).

Preferably, the polymer is a copolymer comprising repeat units of formula (I) and one or more co-repeat units. If co-repeat units are present then the repeat units of formula (I) may form between 0.1-99 mol % of the repeat units of the polymer, optionally 1-60 or 1-50 mol %.

Exemplary co-repeat units are C₆₋₂₀ arylene repeat units or 5-20 membered heteroarylene repeat units, each of which may be unsubstituted or substituted with one or more substituents R² wherein R² is as described above.

Exemplary co-repeat units are repeat units of formulae (IV)-(VI):

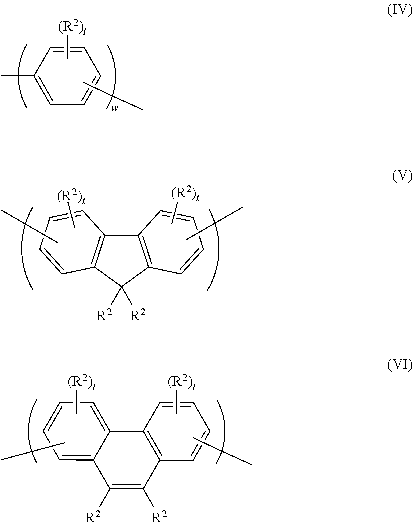

wherein t is 0, 1, 2 or 3 and w is 1, 2 or 3.

Polymers as described anywhere herein suitably have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of polymers described anywhere herein may be 1×10³ to 1×10⁸, and preferably 1×10⁴ to 1×10⁷.

Polymers as described anywhere herein are suitably amorphous polymers.

n-Dopant

In the case where the n-dopant dopes the material comprising a unit of formula (I) spontaneously, it is optionally an n-dopant having a HOMO or semi-occupied molecular orbital (SOMO) level that is shallower (closer to vacuum) than the LUMO level of the polymer. Preferably, the n-dopant has a HOMO level that is at least 0.1 eV shallower than the LUMO level of the material comprising a unit of formula (I), optionally at least 0.5 eV. In this case, the n-dopant is preferably an electron donor.

In the case where the n-dopant dopes the material comprising a unit of formula (I) upon activation, the n-dopant has a HOMO level that is the same as or, preferably, deeper (further from vacuum) than the LUMO level of the material comprising a unit of formula (I), optionally at least 1 eV or 1.5 eV deeper. Accordingly, limited or no spontaneous doping occurs upon mixing of the material comprising a unit of formula (I) and such an n-dopant at 20° C., and limited or no spontaneous doping occurs if the n-dopant is covalently bound to the polymer. An n-dopant may be a hydride donor. An n-dopant may be a material that is capable of converting to a radical that can donate an electron from a SOMO level.

Exemplary n-dopants comprise a 2,3-dihydro-benzoimidazole group, optionally a 2,3-dihydro-1H-benzoimidazole group.

The n-dopant is preferably a compound of formula (III):

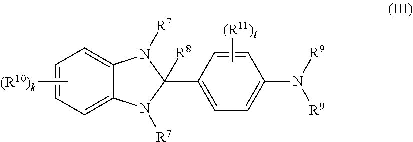

wherein:
each R⁷ is independently a C₁₋₂₀ hydrocarbyl group, optionally a C₁₋₁₀ alkyl group;
R⁸ is H or a C₁₋₂₀ hydrocarbyl group, optionally H, C₁₋₁₀ alkyl or C₁₋₁₀ alkylphenyl;
each R⁹ is independently a C₁₋₂₀ hydrocarbyl group, optionally C₁₋₁₀ alkyl, phenyl or phenyl substituted with one or more C₁₋₁₀ alkyl groups;
each R¹⁰ is independently a substituent and k is 0 or a positive integer; and
each R¹¹ is independently a substituent and 1 is 0 or a positive integer.

Preferably, at least one of k and 1 is at least 1 and R¹⁰ and/or R¹¹ is an ionic substituent, optionally an ionic substituent of formula (VIII).

Exemplary n-dopants include the following:

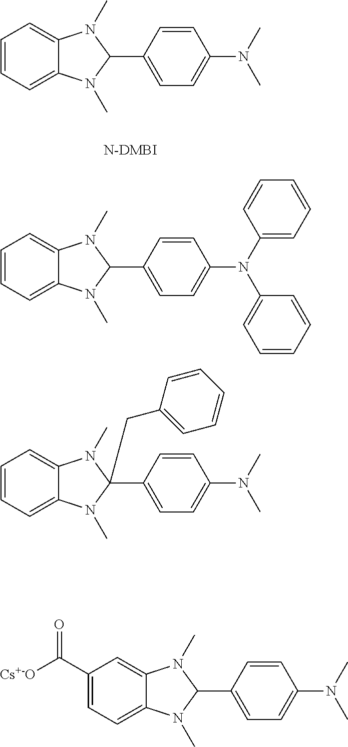

N-DMBI is disclosed in Adv. Mater 2014, 26, 4268-4272, the contents of which are incorporated herein by reference.

Other exemplary n-dopants are leuco crystal violet disclosed in J. Phys. Chem. B, 2004, 108 (44), pp 17076-17082, the contents of which are incorporated herein by reference, and NADH.

The n-dopant may be mixed with the material comprising a unit of formula (I) or may be covalently bound thereto.

A substituent R² of a co-repeat unit of a polymer comprising repeat units of formula (I) as described above may comprise or consist of an n-dopant group. The n-dopant group may be bound to a co-repeat unit in the polymer backbone or may be spaced apart therefrom by a spacer group. Exemplary spacer groups are phenylene; C₁₋₂₀ alkylene; and phenylene-C₁₋₂₀ alkylene wherein one or more non-adjacent C atoms of the alkylene group may be replaced with O, S, CO or COO.

The n-dopant may be a non-polymeric compound, for example a compound of formula (III), or may be a n-dopant polymer substituted with n-dopant groups that may be covalently bound directly to the backbone of the n-dopant polymer or spaced apart therefrom by a spacer group as described above.

The backbone of an n-dopant polymer may be non-conjugated or may be conjugated. Preferably, the n-dopant polymer is a conjugated polymer comprising unsubstituted or substituted C₆₋₂₀ arylene and/or 5-20 membered heteroarylene repeat units that may be unsubstituted or substituted with one or more substituents R² as described herein. Preferably the n-dopant polymer comprises a group of formula (IIIa):

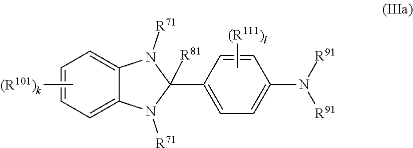

wherein R⁷¹, R⁸¹, R⁹¹, R¹⁰¹ and R¹¹¹ are as described with reference to R⁷, R⁸, R⁹, R¹⁰ and R¹¹ respectively of formula (III), with the proviso that one of R⁷¹, R⁸¹, R⁹¹, R¹⁰¹ and R¹¹¹ is a direct bond to the polymer backbone or to a spacer group between the polymer backbone and the n-doping group of formula (IIIa); and k and 1 are as described with reference to formula (III). Exemplary spacer groups are phenylene; C₁₋₂₀ alkylene; and C₁₋₂₀ alkylene phenylene, wherein one or more non-adjacent C atoms of the alkylene group may be replaced with O, S, CO or COO. Phenylene groups of the spacer may be unsubstituted or substituted with one or more substituents, optionally substituents selected from C₁₋₁₂ alkyl, C₁₋₁₂ alkoxy and ionic substituents A as described herein.

The backbone of an n-dopant polymer may be non-conjugated or may be conjugated. Preferably, the n-dopant polymer is a conjugated polymer comprising unsubstituted or substituted C₆₋₂₀ arylene and/or or 5-20 membered heteroarylene repeat units in the backbone thereof. Substituents of said arylene or heteroarylene repeat units are optionally selected from substituents R² as described with reference to formula (I).

n-dopant groups covalently bound to a polymer include the following:

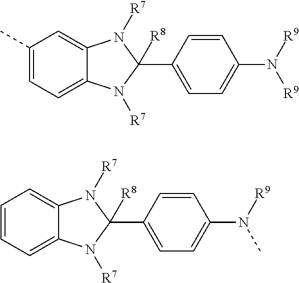

wherein [symbol] is a bond to the co-repeat unit in the polymer backbone or, if present, a spacer group.

The weight ratio of the polymer comprising a repeat unit of formula (I): n-dopant may be in the range of 99:1-30:70. Optionally, the n-dopant is present in a molar excess with respect to the polymer comprising a repeat unit of formula (I).

### Polymer Formation

Conjugated polymers comprising repeat units of formula (I) may be formed by polymerising monomers comprising leaving groups that leave upon polymerisation of the monomers to form conjugated repeat units. Exemplary polymerization methods include, without limitation, Yamamoto polymerization as described in, for example, T. Yamamoto, “Electrically Conducting And Thermally Stable pi-Conjugated Poly(arylene)s Prepared by Organometallic Processes”, Progress in Polymer Science 1993, 17, 1153-1205, the contents of which are incorporated herein by reference and Suzuki polymerization as described in, for example, WO 00/53656, WO 2003/035796, and U.S. Pat. No. 5,777,070, the contents of which are incorporated herein by reference.

Preferably, the polymer is formed by polymerising monomers comprising boronic acid or boronic ester group leaving groups bound to aromatic carbon atoms of the monomer with monomers comprising leaving groups selected from halogen, sulfonic acid or sulfonic ester, preferably bromine or iodine, bound to aromatic carbon atoms of the monomer in the presence of a palladium (0) or palladium (II) catalyst and a base.

Exemplary boronic esters have formula (XII):

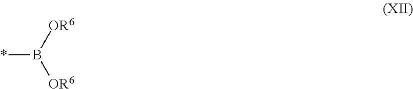

wherein R⁶ in each occurrence is independently a C₁₋₂₀ alkyl group, * represents the point of attachment of the boronic ester to an aromatic ring of the monomer, and the two groups R⁶ may be linked to form a ring.

The polymer comprising repeat units of formula (I) may be formed by polymerization of a monomer for forming this repeat unit, optionally with monomers for forming one or more co-repeat units.

The polymer may be end-capped with any suitable end-capping group. An end-capping reactant for forming the end-capping group may be added to the polymerization mixture at the outset of, during or at the end of polymerization. Exemplary end-capping groups are C₆₋₂₀ aryl groups, optionally phenyl.

### Activation

In the case where the n-dopant does not spontaneously dope the material comprising a unit of formula (I) on contact at 20° C., n-doping may be effected by activation. Preferably, n-doping is effected after formation of a device comprising the layer containing the material comprising a unit of formula (I) and n-dopant, and optionally after encapsulation. Activation may be by excitation of the n-dopant and/or the material comprising a unit of formula (I).

Exemplary activation methods are thermal treatment and irradiation.

Optionally, thermal treatment is at a temperature in the range 80° C. to 170° C., preferably 120° C. to 170° C. or 140° C. to 170° C.

Thermal treatment and irradiation as described herein may be used together.

For irradiation, any wavelength of light may be used, for example a wavelength having a peak in the range of about 200-700 nm.

Optionally, the peak showing strongest absorption in the absorption spectrum of the material comprising a unit of formula (I) is in the range of 400-700 nm. Preferably, the strongest absorption of the n-dopant is at a wavelength below 400 nm.

The present inventors have surprisingly found that exposure to electromagnetic radiation of a composition of a material comprising a unit of formula (I) and a n-dopant that does not spontaneously dope the material comprising a unit of formula (I) results in n-doping even if the electromagnetic radiation is not at the peak absorption wavelength of the n-dopant.

The light emitted from the light source suitably overlaps with an absorption feature, for example an absorption peak or shoulder, of the absorption spectrum of the material comprising a unit of formula (I). Optionally, the light emitted from the light source has a peak wavelength within 25 nm, 10 nm or 5 nm of an absorption maximum wavelength of the material comprising a unit of formula (I), however it will be appreciated that a peak wavelength of the light need not coincide with an absorption maximum wavelength of the polymer. Optionally, irradiation time is between 1 second and 1 hour, optionally between 1-30 minutes.

In one embodiment, the light emitted from the light source used for irradiation is in the range 400-700 nm. Optionally, the electromagnetic radiation has a peak wavelength greater than 400 nm, optionally greater than 420 nm, optionally greater than 450 nm. Optionally, there is no overlap between an absorption peak in the absorption spectrum of the n-dopant and the wavelength(s) of light emitted from the light source.

In another embodiment, the light-emitted from the light source used for irradiation has a peak wavelength of 400 nm or less.

Optionally, the electromagnetic radiation source is an array of inorganic LEDs. The electromagnetic radiation source may produce radiation having one or more than one peak wavelengths.

Preferably, the electromagnetic radiation source has a light output of at least 2000 mW, optionally at least 3000 mW, optionally at least 4000 mW.

Any suitable electromagnetic radiation source may be used to irradiate the film including, without limitation, fluorescent tube, incandescent bulb and organic or inorganic LEDs.

The extent of doping may be controlled by one or more of: the acceptor material/n-dopant ratio; the temperature and duration of heating if activation comprises heating; and the peak wavelength and intensity of the light and the duration of irradiation of the film if activation comprises irradiation.

The n-doped material may be an extrinsic or degenerate semiconductor.

In manufacture of an organic electronic device, such as an OLED as described in FIG. 1, activation may take place during device formation or after the device has been formed.

Preferably, activation to cause n-doping takes place after the device has been formed and encapsulated. The device may be manufactured in an environment in which limited or no spontaneous doping occurs, for example a room temperature environment wherein the device is exposed to little or no wavelengths of light that induce n-doping until after encapsulation of the device, for example an environment illuminated by light having a longer wavelength than that of the electromagnetic radiation source such as a clean room illuminated with yellow light.

In the case of an OLED as described in FIG. 1, the material comprising a unit of formula (I) and the n-dopant may be provided between the organic light-emitting layer 105 and the cathode 109.

For activation by irradiation, the film may then irradiated through the anode 101, in the case of a device formed on a transparent substrate 101 and having a transparent anode 103, such as ITO, or the film may be irradiated through the cathode 109 in the case of a device with a transparent cathode. The wavelength used to induce n-doping may be selected to avoid wavelengths that are absorbed by layers of the device between the electromagnetic radiation source and the film.

### Light-Emitting Layers

The OLED 100 may contain one or more light-emitting layers.

Light-emitting materials of the OLED 100 may be fluorescent materials, phosphorescent materials or a mixture of fluorescent and phosphorescent materials. Light-emitting materials may be selected from polymeric and non-polymeric light-emitting materials. Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12 1737-1750, 2000, the contents of which are incorporated herein by reference. Light-emitting layer 107 may comprise a host material and a fluorescent or phosphorescent light-emitting dopant. Exemplary phosphorescent dopants are row 2 or row 3 transition metal complexes, for example complexes of ruthenium, rhodium, palladium, rhenium, osmium, iridium, platinum or gold.

A light-emitting layer of an OLED may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

A light-emitting layer may contain a mixture of more than one light-emitting material, for example a mixture of light-emitting materials that together provide white light emission. A plurality of light-emitting layers may together produce white light.

A fluorescent light-emitting layer may consist of a light-emitting material alone or may further comprise one or more further materials mixed with the light-emitting material. Exemplary further materials may be selected from hole-transporting materials; electron-transporting materials and triplet-accepting materials, for example a triplet-accepting polymer as described in WO 2013/114118, the contents of which are incorporated herein by reference.

### Cathode

The cathode may comprise one or more layers. Preferably, the cathode comprises or consists of a layer in contact with the electron injecting layer that comprises or consists of one or more conductive materials. Exemplary conductive materials are metals, preferably metals having a work function of at least 4 eV, optionally aluminium, copper, silver or gold or iron. Exemplary non-metallic conductive materials include conductive metal oxides, for example indium tin oxide and indium zinc oxide, graphite and graphene. Work functions of metals are as given in the CRC Handbook of Chemistry and Physics, 12-114, 87^{th} Edition, published by CRC Press, edited by David R. Lide. If more than one value is given for a metal then the first listed value applies.

The cathode may be opaque or transparent. Transparent cathodes are particularly advantageous for active matrix devices because emission through a transparent anode in such devices is at least partially blocked by drive circuitry located underneath the emissive pixels.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Hole-Transporting Layer

A hole transporting layer may be provided between the anode 103 and the light-emitting layer 105.

The hole-transporting layer may be cross-linked, particularly if an overlying layer is deposited from a solution. The crosslinkable group used for this crosslinking may be a crosslinkable group comprising a reactive double bond such and a vinyl or acrylate group, or a benzocyclobutane group. Crosslinking may be performed by thermal treatment, preferably at a temperature of less than about 250° C., optionally in the range of about 100-250° C.

A hole transporting layer may comprise or may consist of a hole-transporting polymer, which may be a homopolymer or copolymer comprising two or more different repeat units. The hole-transporting polymer may be conjugated or non-conjugated. Exemplary conjugated hole-transporting polymers are polymers comprising arylamine repeat units, for example as described in WO 99/54385 or WO 2005/049546 the contents of which are incorporated herein by reference. Conjugated hole-transporting copolymers comprising arylamine repeat units may have one or more co-repeat units selected from arylene repeat units, for example one or more repeat units selected from fluorene, phenylene, phenanthrene naphthalene and anthracene repeat units, each of which may independently be unsubstituted or substituted with one or more substituents, optionally one or more C₁₋₄₀ hydrocarbyl substituents.

If present, a hole transporting layer located between the anode and the light-emitting layer 105 preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer in order to provide a small barrier to hole transport between these layers.

Preferably a hole-transporting layer, more preferably a crosslinked hole-transporting layer, is adjacent to the light-emitting layer 105.

A hole-transporting layer may consist essentially of a hole-transporting material or may comprise one or more further materials. A light-emitting material, optionally a phosphorescent material, may be provided in the hole-transporting layer.

A phosphorescent material may be covalently bound to a hole-transporting polymer as a repeat unit in the polymer backbone, as an end-group of the polymer, or as a side-chain of the polymer. If the phosphorescent material is provided in a side-chain then it may be directly bound to a repeat unit in the backbone of the polymer or it may be spaced apart from the polymer backbone by a spacer group. Exemplary spacer groups include C₁₋₂₀ alkyl and aryl-C₁₋₂₀ alkyl, for example phenyl-C₁₋₂₀ alkyl. One or more carbon atoms of an alkyl group of a spacer group may be replaced with O, S, C═O or COO.

Emission from a light-emitting hole-transporting layer and emission from light-emitting layer 105 may combine to produce white light.

### Hole Injection Layers

A conductive hole injection layer, which may be formed from a conductive organic or inorganic material, may be provided between the anode 103 and the light-emitting layer 105 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### Encapsulation

In the case where the n-dopant does not spontaneously dope the material comprising a unit of formula (I), the n-dopant is preferably activated to cause n-doping as described herein after encapsulation of the device containing the film to prevent ingress of moisture and oxygen.

Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

The substrate on which the device is formed preferably has good barrier properties such that the substrate together with the encapsulant form a barrier against ingress of moisture or oxygen. The substrate is commonly glass however alternative substrates may be used, in particular where flexibility of the device is desirable. For example, the substrate may comprise one or more plastic layers, for example a substrate of alternating plastic and dielectric barrier layers or a laminate of thin glass and plastic.

### Formulation Processing

Light-emitting layer 105 and electron-injecting layer 107 may be formed by any method including evaporation and solution deposition methods. Solution deposition methods are preferred.

Formulations suitable for forming light-emitting layer 105 and electron-injecting layer 107 may each be formed from the components forming those layers and one or more suitable solvents.

Preferably, light-emitting layer 105 is formed by depositing a solution in which the solvent is one or more non-polar solvent materials, optionally benzenes substituted with one or more substituents selected from C₁₋₁₀ alkyl and C₁₋₁₀ alkoxy groups, for example toluene, xylenes and methylanisoles, and mixtures thereof.

Optionally, the electron-injecting layer 107 is formed by depositing a material comprising a unit of formula (I) and an n-dopant together, preferably from a solution, or by forming adjacent layers wherein the adjacent layers are independently formed by any suitable deposition method, preferably from a solution, one layer comprising the material comprising a unit of formula (I) and the other layer comprising the dopant. If the material comprising a unit of formula (I) and n-dopant are deposited separately then n-doping to form the charge-transfer salt may occur spontaneously upon contact of the two materials and/or upon activation. It will be appreciated that the electron-injection layer as described herein may be formed by separate deposition of the material comprising a unit of formula (I) and n-dopant; and the electron-injection layer may comprise undoped material comprising a unit of formula (I) and/or free dopant, the concentrations of which may vary across the thickness of the layer.

Preferably, the electron-injecting layer is formed from a polar solvent, optionally a protic solvent, optionally water or an alcohol; dimethylsulfoxide; propylene carbonate; or 2-butanone which may avoid or minimise dissolution of the underlying layer if the materials of the underlying layer are not soluble in polar solvents.

Exemplary alcohols include methanol ethanol, propanol, butoxyethanol and monofluoro-, polyfluoro- or perfluoro-alcohols, optionally 2,2,3,3,4,4,5,5-Octafluoro-1-pentanol.

Particularly preferred solution deposition techniques including printing and coating techniques such spin-coating, inkjet printing and lithographic printing.

Coating methods are particularly suitable for devices wherein patterning of the light-emitting layer is unnecessary—for example for lighting applications or simple monochrome segmented displays.

Printing methods are particularly suitable for high information content displays, in particular full colour displays. A device may be inkjet printed by providing a patterned layer over the anode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, slot die coating, roll printing and screen printing.

### Applications

A layer comprising the doped material comprising a unit of formula (I), preferably a doped polymer comprising repeat units of formula (I), has been described with reference to the electron-injection layer of an organic light-emitting device formed over an organic light-emitting layer, however it will be appreciated that the layer formed as described herein may be used in other organic electronic devices, and may be formed on a surface of said organic electronic device by methods as described herein, for example as an electron-extraction layer of an organic photovoltaic device or organic photodetector; as an auxiliary electrode layer of a n-type organic thin film transistor or as an n-type semiconductor in a thermoelectric generator.

### EXAMPLES

### Measurements

UV-visible absorption spectra of pristine and n-doped acceptor materials as described herein were measured by spin-coating onto glass substrates, as blend with the dopant. The film thicknesses were in the range of 20-100 nm.

After spin-coating and drying, the polymer films were encapsulated in a glove box, in order to exclude any contact of the n-doped films with air.

After the encapsulation, UV-vis absorption measurements were conducted with a Carey-5000 Spectrometer, followed by successive exposures to visible light and repeat UV-VIS measurements.

HOMO, SOMO and LUMO levels as described anywhere herein are as measured by square wave voltammetry.

### Equipment:

CHI660D Electrochemical workstation with software (IJ Cambria Scientific Ltd))

### CHI 104 3 mm Glassy Carbon Disk Working Electrode (IJ Cambria Scientific Ltd))

Platinum wire auxiliary electrode

### Reference Electrode (Ag/AgCl) (Havard Apparatus Ltd)

### Chemicals

| | |
|---|---|
| Acetonitrile (Hi-dry anhydrous grade-ROMIL) | (Cell solution solvent) |
| Toluene (Hi-dry anhydrous grade) | (Sample preparation |
| | solvent) |
| Ferrocene-FLUKA | (Reference standard) |
| Tetrabutylammoniumhexafluorophosphate- | (Cell solution salt) |
| FLUKA) | |

### Sample Preparation

The acceptor polymers were spun as thin films (˜20 nm) onto the working electrode; the dopant material was measured as a dilute solution (0.3 wt %) in toluene.

### Electrochemical Cell

The measurement cell contains the electrolyte, a glassy carbon working electrode onto which the sample is coated as a thin film, a platinum counter electrode, and a Ag/AgCl reference glass electrode. Ferrocene is added into the cell at the end of the experiment as reference material (LUMO (ferrocene)=−4.8 eV).

### Monomer Example 1

Monomer Example 1 was prepared according to the following reaction scheme:

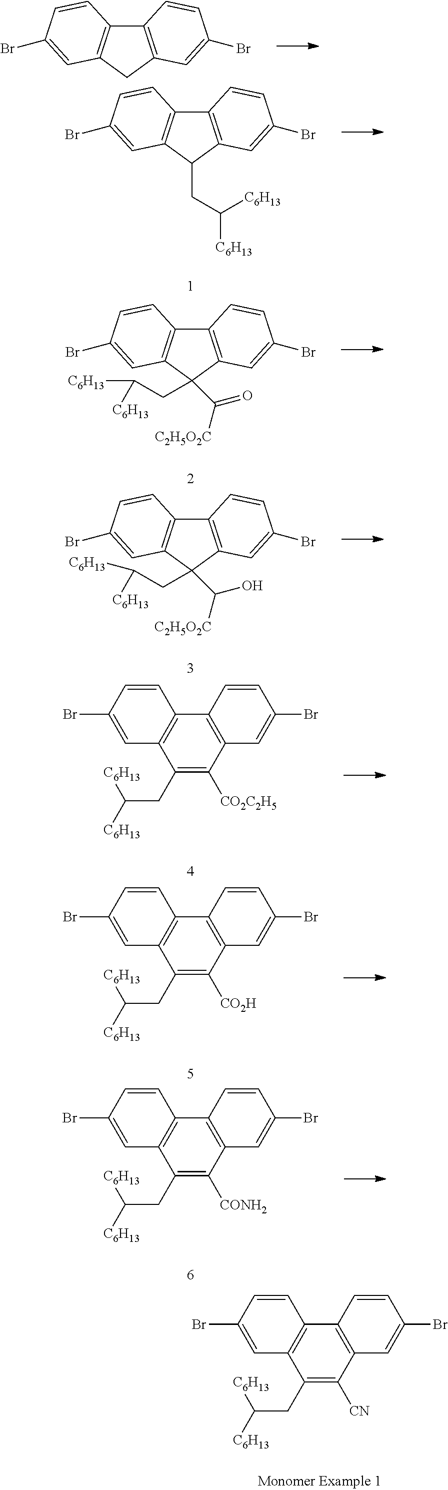

### Intermediate 1:

To a mixture of 2,7-dibromofluorene (150 g, 0.4629 mol) in diethyl ether (1.2 L) was added n-BuLi (203.7 ml, 0.5092 mol) at room temperature. The reaction mixture was stirred at room temperature for 2 hours. 1-bromo-2-hexyloctane (146.25 g, 0.5555 mol) in diethyl ether (1.2 L) was added to it slowly at room temperature. The reaction mixture was stirred at room temperature for 16 hours. Citric acid solution (20% aqueous, 1500 ml) was added and mixture was extracted with ethyl acetate (2000 ml×2). The combined organic layer were washed with brine (1000 ml), dried over sodium sulphate and concentrated. Residue was purified twice by column chromatography using silica gel and hexanes as eluent to obtain 153 g of Intermediate 1 as yellow viscous oil, 64% yield.

¹H-NMR (400 MHz, CDCl3): δ [ppm] 0.90 (t, J=7.00 Hz, 6H), 1.25-1.38 (m, 20H), 1.62-1.69 (m, 1H), 1.75 (t, J=6.80 Hz, 2H), 3.96 (t, J=6.76 Hz, 1H), 7.49 (dd, J=1.56, 8.10 Hz, 2H), 7.58 (d, J=8.12 Hz, 2H), 7.62 (s, 2H)

### Intermediate 2:

To a suspension of sodium hydride (15.38 g, 0.3849 mol) in tetrahydrofuran (500 ml) was added slowly a solution of Intermediate 1 (100 g, 0.1923 mol) in tetrahydrofuran (200 ml) at room temperature. The reaction mixture was stirred at room temperature for 4 hours. It was then added to a solution of ethyl oxalyl chloride (52.5 g, 0.3849 mol) in tetrahydrofuran (300 ml) at −20° C. The reaction mixture temperature was allowed to warm up to room temperature and stirred for 16 hours. It was poured into ice-water and extracted with ethyl acetate (500 ml×2). Combined ethyl acetate layers were dried over sodium sulphate and concentrated. The was purified by column chromatography using silica gel and 2% ethyl acetate in hexanes as eluent to obtain 63 g of Intermediate 2, 53% yield.

### Intermediate 3:

To a solution of Intermediate 2 (120 g, 0.1934 mol) in tetrahydrofuran (1200 ml) was added lithium aluminium hydride (25.14 ml, 2M solution in tetrahydrofuran, 0.0503 mol) at −20° C. The reaction mixture was then stirred at room temperature for 5 hours. Ethyl acetate (100 ml) was added to it and mixture was filtered through celite. The filtrate was concentrated and residue was purified by column chromatography using silica gel and a gradient of 2% to 5% ethyl acetate in hexanes as eluent to obtain 91 g of Intermediate 3, 76% yield.

### Intermediate 4:

To a solution of Intermediate 3 (90 g, 0.1446 mol) in toluene (900 ml) was added phosphorus pentoxide (82 g, 0.5784 mol) at room temperature. The reaction mixture was heated to 110° C. and stirred for 5 hours. It was then cooled to room temperature and ice-water (1000 ml) was added to it. The mixture was extracted with ethyl acetate (500 ml×2). Combined organic layers were washed with brine (500 ml), dried over sodium sulphate and concentrated. Residue was purified twice by column chromatography using silica gel and 2% ethyl acetate in hexanes as eluent to obtain 49 g of Intermediate 4, 56% yield.

### Intermediate 5:

To a solution of Intermediate 4 (49 g, 0.08111 mol) in a mixture of tetrahydrofuran (250 ml) and methanol (250 ml) was added potassium hydroxide powder (90.8 g, 1.6212 mol). The mixture was heated to 130° C. in a sealed tube and stirred for 40 hours. The reaction was cool to −10° C. and concentrated hydrochloric acid (120 ml) was added it until acidic pH was obtained. The mixture was extracted with ethyl acetate (500 ml×2). Combined ethyl acetate layers were dried over sodium sulphate and concentrated. Residue was purified by column chromatography using silica gel and a gradient of 5% to 10% ethyl acetate in hexanes as eluent to obtain 25.3 g of Intermediate 5, 54% yield.

¹H-NMR (300 MHz, DMSO-d6): δ [ppm] 0.75 (t, J=6.93 Hz, 6H), 1.08-1.38 (m, 20H), 1.75-1.92 (m, 1H), 3.05 (d, J=6.87 Hz, 2H), 7.83-7.87 (m, 2H), 7.90 (s, 1H), 8.29 (s, 1H), 8.80-8.85 (m, 2H).

### Intermediate 6:

A solution of Intermediate 5 (25 g, 0.0434 mol) in thionyl chloride (250 ml) was refluxed for 3 hours. Thionyl chloride was then distilled off and crude acid chloride was dissolved in tetrahydrofuran (200 ml). It was added to the solution of ammonia gas in tetrahydrofuran (800 ml) at −20° C. The mixture was then stirred at room for 3 hours. Tetrahydrofuran was distilled off and the residue was diluted with water. It was extracted with ethyl acetate (500 ml×2). Combined organic layers were dried over sodium sulphate and concentrated. The residue was purified by column chromatography using silica gel and 10% ethyl acetate in hexanes as eluent to obtain 22.4 g of Intermediate 6, 90% yield.

### Monomer Example 1

To a solution of Intermediate 6 (22 g, 0.0383 mol) in toluene (440 ml) was added phosphorus pentoxide (10.8 g, 0.0766 mol). Reaction mixture was heated to 110° C. and stirred for 4 hours. The reaction mixture was allowed cool down to room temperature and quenched over ice water (500 ml The mixture was extracted with ethyl acetate (500 ml×2), dried over sodium sulphate and concentrated. The residue was purified by column chromatography using silica gel and 100% hexane as eluent to obtain 20.6 g of Monomer Example 1 as an off-white solid, 97% yield.

¹H-NMR (400 MHz, CDCl3): δ [ppm] 0.87 (t, J=6.92 Hz, 6H), 1.12-1.39 (m, 16H), 1.41-1.50 (m, 4H), 1.87-1.98 (m, 1H), 3.34 (d, J=7.20 Hz, 2H), 7.82 (dd, J=1.96, 8.86 Hz, 1H), 7.89 (dd, J=1.88, 8.88 Hz, 1H), 8.30 (s, 1H), 8.87 (s, 1H), 8.48 (d, J=8.64 Hz, 1H), 8.54 (d, J=8.96 Hz, 1H).

### Monomer Example 2

Monomer Example 2 was prepared according to the following reaction scheme:

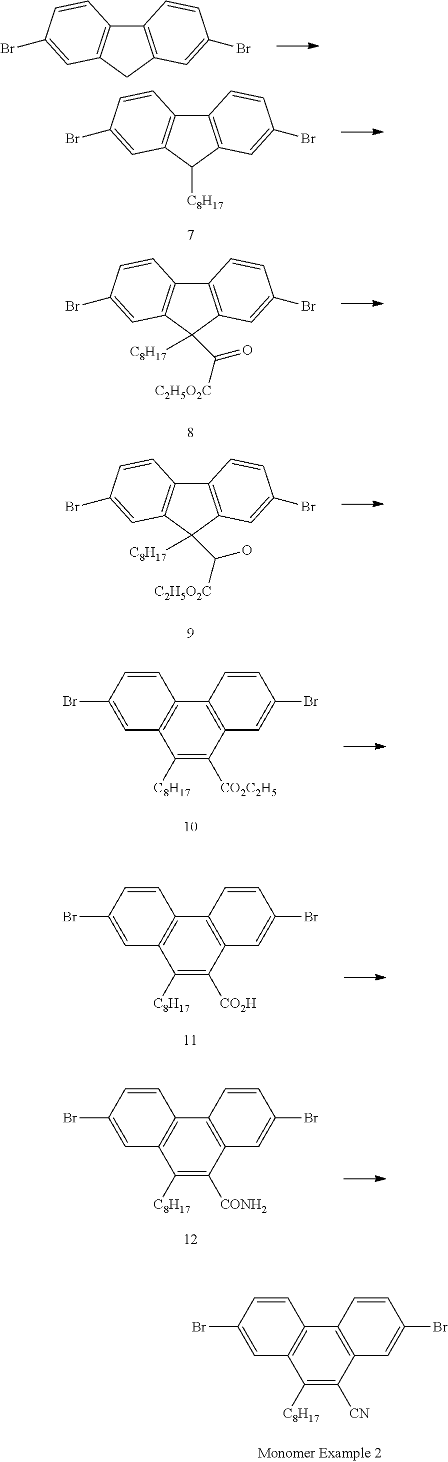

### Intermediate 7:

To a solution of 2,7-dibromofluorene (250 g, 0.772 mol) in diethyl ether (3 L) was added n-BuLi (1.31M in hexane, 766 ml, 1.000 mol) was added slowly at room temperature. The mixture was stirred at room temperature for 24 hours. It was then cooled to 0° C. and n-bromooctane (223.6 g, 1.158 mol) was added drop wise. The reaction mixture was stirred at room temperature for 16 hours then quenched with water (500 ml) and extracted with ethyl acetate (1000 ml×2). The combined organic layers were washed with brine (1000 ml), dried over anhydrous sodium sulphate and concentrated. Residue, combined with crude from other batches, was purified by column chromatography using silica and hexane as eluent. Resulting solid was recrystallized using hexane at −40° C. to afford 430 g (40%) of intermediate 7 with 99.5% HPLC purity as a white solid.

¹H-NMR (400 MHz, CDCl3): δ [ppm] 0.88 (t, J=6.80 Hz, 3H), 1.11-1.17 (m, 2H), 1.22-1.29 (m, 10H), 1.95-2.00 (m, 2H), 3.96 (t, J=5.60 Hz, 1H), 7.50 (dd, J=8.40, 2.0 Hz, 2H), 7.57 (d, J=8.00 Hz, 2H), 7.63 (s, 2H).

### Intermediate 8:

A solution of Intermediate 7 (400 g, 0.917 mol) in tetrahydrofuran (1200 ml) purged with argon for 1.5 hours was added slowly at room temperature to a mixture of potassium tert-butoxide (103 g, 0.917 mol) in tetrahydrofuran (1200 ml) purged with for 1.5 hours. The mixture was stirred at room temperature for 1 hour. It was then added to a solution of ethyl oxalyl chloride (187.84 g, 1.376 mmol) in tetrahydrofuran (2400 ml) at −20° C. The mixture was stirred at −20° C. for 1 hour and neutralized with citric acid solution (15% aqueous, 300 ml). Mixture was extracted with ethyl acetate (1 L×2). The combined organic layer were washed with brine (500 ml), dried over sodium sulphate and concentrated under reduced pressure. The residue was purified by column chromatography using silica gel and 5% ethyl acetate in hexanes as eluent to yield 310 g of intermediate 8 with 98.01% HPLC purity, 63% yield.

¹H-NMR (400 MHz, CDCl3): δ [ppm] 0.65-0.67 (m, 2H), 0.82-0.86 (m, 3H), 0.91-0.96 (m, 3H), 1.12-1.28 (m, 10H), 2.29-2.33 (m, 2H), 3.87-3.92 (m, 2H), 7.52 (d, J=1.60 Hz, 2H), 7.57-7.65 (m, 4H)

### Intermediate 9:

Nitrogen was bubbled into a solution of Intermediate 8 (310 g, 0.578 mol) in tetrahydrofuran (1200 ml) for 1 hour. A solution of lithium aluminium hydride solution (2M in THF, 75.1 mL, 0.150 mol) was added slowly to it at −20° C. The mixture was stirred at room temperature for 2 hours, then cooled to 0° C. and ethyl acetate (100 mL) was added. Mixture once at room temperature was filtered through celite. Filtrate was concentrated under reduced pressure. The residue was purified by column chromatography using silica gel and a mixture of chloroform in ethyl acetate. Resulting solid was recrystallized using hexane at −20° C. to yield 230 g of Intermediate 9 with 97.21% HPLC purity, 74% yield.

¹H-NMR (400 MHz, CDCl3): δ [ppm] 0.58-0.68 (m, 2H), 0.72 (t, J=6.80 Hz, 3H), 0.85 (t, J=7.20 Hz, 3H), 1.11-1.16 (m, 8H), 1.22-1.27 (m, 2H), 2.08-2.16 (m, 1H), 2.38-2.45 (m, 1H), 3.29 (d, J=6.40 Hz, 1H), 3.64-3.72 (m, 2H), 4.58 (d, J=6.40 Hz, 2H), 7.52 (d, J=2.80 Hz, 4H), 7.56 (s, 1H), 7.72 (s, 1H).

### Intermediate 10:

To a solution of Intermediate 9 (110 g, 0.205 mol) in toluene (1100 ml) was added phosphorus pentoxide (116.1 g, 0.818 mol). Reaction mixture was heated to 110° C. and stirred for 30 minutes. Mixture was cooled to room temperature and ice-water (1000 ml) was added to it. It was then extracted with ethyl acetate (500 ml×2). The combined organic layer were washed with brine (500 ml), dried over sodium sulphate and concentrated under reduced pressure. The residue was purified twice by column chromatography using silica gel and 2% ethyl acetate in hexanes as eluent. Resulting product was stirred in hexanes at room temperature for 16 hours and solid was filtered to yield 72 g of Intermediate 10 with 90.85% HPLC purity and 21 g with 78.2% HPLC purity. Lower purity solid was recrystallized from hexane. It was then combined with the fraction at 90.85% purity and recrystallized from hexanes yield 66.1 g of Intermediate 10 with 99.38% HPLC purity, 31% yield.

### Intermediate 11:

A mixture of Intermediate 10 (33 g, 0.0635 mol) and potassium hydroxide powder (35.5 g, 0.6346 mol) in tetrahydrofuran (170 ml) and methanol (170 mL) was heated to 120° C. in a sealed tube for 24 hours. The mixture was cooled to room temperature and concentrated to remove the methanol. Another 33 g batch reaction was carried out and combined. The combined crude mixtures were quenched with water (600 ml) and extracted with dichloromethane (500 ml×2). Solid precipitated, it was filtered and washed with dichloromethane. It was neutralized with HCl (1.5N aqueous) to pH 3 and extracted with dichloromethane (200 ml×2). The combined organic layers were dried over sodium sulphate and concentrated under reduced pressure. The residue was purified by column chromatography using silica gel and a gradient of 30% to 70% ethyl acetate in hexanes. Resulting product was stirred in hexanes at room temperature for 16 hours and solid was filtered to yield 56 g of Intermediate 11 with 98.44% HPLC purity, 89% yield.

¹H-NMR (400 MHz, CDCl3): δ [ppm] 0.89 (t, J=6.80 Hz, 3H), 1.25-1.37 (m, 6H), 1.39-1.45 (m, 2H), 1.53-1.60 (m, 2H), 1.77-1.85 (m, 2H), 3.15 (t, J=8.00 Hz, 2H), 7.77 (dd, J=8.80, 2.0 Hz, 1H), 7.83 (dd, J=8.80, 2.0 Hz, 1H), 8.10 (d, J=1.60 Hz, 1H), 8.29 (d, J=2.0 Hz, 1H), 8.50 (d, J=8.80 Hz, 1H), 8.54 (d, J=8.80 Hz, 1H).

### Intermediate 12:

A mixture of Intermediate 11 (56 g, 0.1138 mol) in thionyl chloride (560 ml) was refluxed for 1 hour. Thionyl chloride was distilled off and residue was dissolved in tetrahydrofuran (500 ml). It was added a solution of ammonia gas in tetrahydrofuran (800 ml) at −70° C. The mixture was allowed to attain room temperature and tetrahydrofuran was removed. The residue was diluted with water and extracted with ethyl acetate (500 ml×2). The combined organic layer was dried over sodium sulphate and concentrated under reduced pressure. The residue was purified by column chromatography using silica gel and a gradient of 30-100% ethyl acetate in hexanes as eluent. Resulting product was stirred with hexane and solid was filtered to yield 50 g of Intermediate 12 with 99.10% HPLC purity, 89% yield.

### Monomer Example 2

A mixture of Intermediate 12 (50 g, 0.1018 mol) and phosphorus pentoxide (43.4 g, 0.3055 mol) in toluene (1000 ml) was stirred at 110° C. for 4 hours. The mixture was cooled down to room temperature and quenched over ice-water (400 ml). The mixture was extracted with ethyl acetate (300 ml×4). The combined organic layers were dried over sodium sulphate and concentrated under reduced pressure. The residue was purified by column chromatography using silica gel and chloroform as eluent to yield 35.2 g of Monomer Example 2 with 99.1% HPLC purity and 10.4 g of Monomer Example 2 with 98.0% HPLC purity. The higher purity fraction was stirred with ethyl acetate for 2 hours and filtered to yield 33.4 g of Monomer Example 2 with 99.74% HPLC purity, 69% yield.

¹H-NMR (400 MHz, CDCl3): δ [ppm] 0.91 (t, J=6.80 Hz, 3H), 1.32-1.37 (m, 6H), 1.37-1.43 (m, 2H), 1.53-1.60 (m, 2H), 1.76-1.84 (m, 2H), 3.38 (t, J=7.60 Hz, 2H), 7.81 (dd, J=8.80, 2.00 Hz, 1H), 7.89 (dd, J=8.80, 2.00 Hz, 1H), 8.28 (d, J=1.60 Hz 1H), 8.43-8.46 (m, 2H), 8.52 (d, J=8.80 Hz, 1H).

### Monomer Example 3

Monomer Example 3 was prepared according to the following reaction scheme:

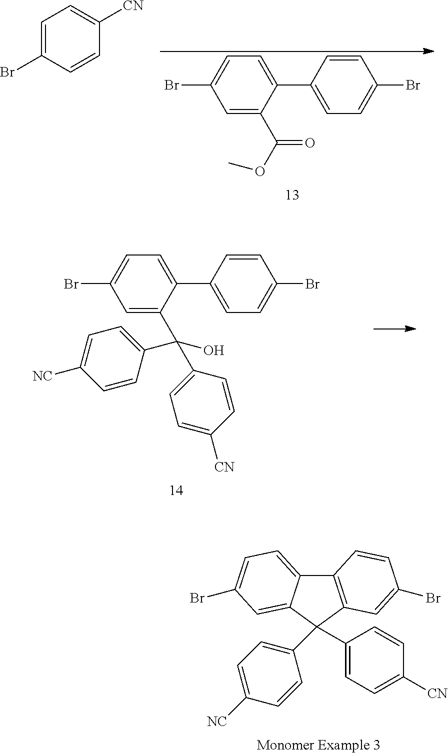 [SMILES: N#Cc1ccc(Br)cc1 ; COC(=O)c1cc(Br)ccc1-c1ccc(Br)cc1 ; N#Cc1ccc(C(O)(c2ccc(C#N)cc2)c2cc(Br)ccc2-c2ccc(Br)cc2)cc1 ; N#Cc1ccc(C2(c3ccc(C#N)cc3)c3cc(Br)ccc3-c3ccc(Br)cc32)cc1]

### Intermediate 14:

N-butyl lithium (2.5M in hexanes, 43 ml, 107.4 mmol) was added to a mixture of 4-bromobenzonitrile (20.0 g, 109.9 mmol) in tetrahydrofuran (300 ml) at −100° C. Mixture was stirred for 2 hours at −100° C. and extra n-butyl lithium (2.5M in hexanes, 10 ml, 25.0 mmol) was added. Mixture was stirred for 30 minutes and a solution of Intermediate 13 (18.5 g, 50.0 mmol) in tetrahydrofuran (35 ml) was added drop wise to it. Reaction was warmed up slowly overnight. It was quenched by adding to it hydrochloric acid (2M aqueous, 50 ml) drop wise at 0° C. Tetrahydrofuran was removed under reduced pressure and residue was extracted with toluene. Organic phase was washed with water (×3), dried over magnesium sulphate and concentrated under reduced pressure to yield 33.2 g of Intermediate 14 as a brown oil.

### Monomer Example 3

Boron trifluoride diethyl etherate (30.7 ml, 250 mmol) was added drop wise to a solution of Intermediate 13 (33.2 g of brown oil) in dichloromethane (80 ml) at 0° C. Mixture was stirred overnight at room temperature and quenched by pouring it into ice-water. Phases were separated and organic phase was stirred for 30 minutes with sodium carbonate (10 wt % aqueous, 80 ml). Phases were separated and organic phase was washed with water (100 ml×3), dried over magnesium sulphate and concentrated under reduced pressure. Residue was stirred with methanol overnight and slurry was filtered. Residue was purified by filtering it through a basic alumina/florisil plug (a layer of florisil packed on top of a layer of basic alumina) using toluene as eluent, followed by column chromatography using silica gel and toluene followed by ethyl acetate as eluent. Resulting product was recrystallized from a mixture of chloroform and heptane to yield 2.65 g of Monomer Example 3, 98.9% HPLC purity, 10% yield.

¹H-NMR (600 MHz, CDCl3): δ [ppm] 7.22 (m, 4H), 7.39 (d, J=1.6 Hz, 2H), 7.56 (dd, J=1.7, 8.1 Hz, 2H), 7.59 (m, 4H), 7.64 (d, J=8.2 Hz, 2H).

### Monomer Example 4

Monomer Example 4 was prepared according to the following reaction scheme:

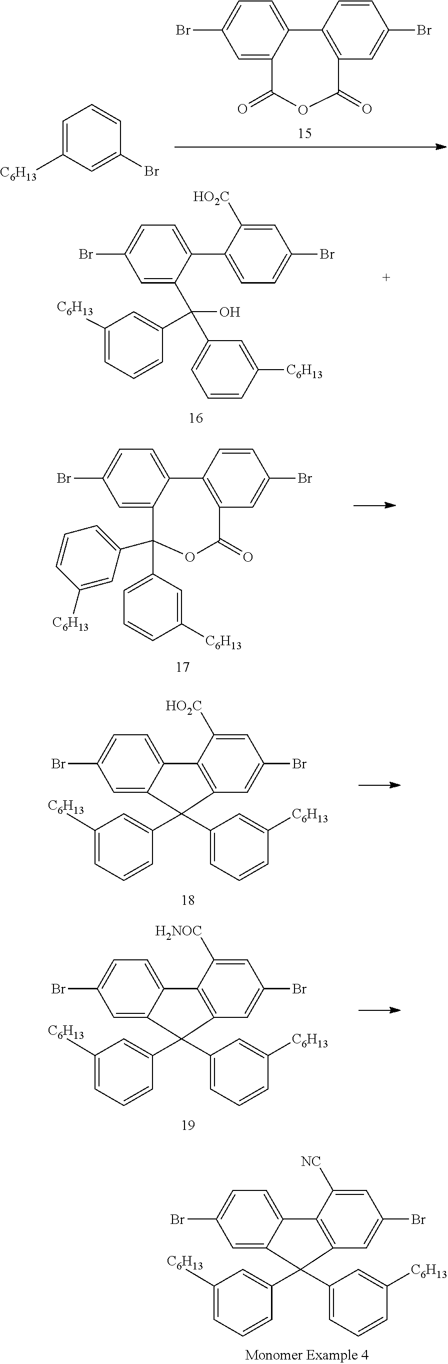

### Intermediate 16 and 17:

A solution of 3-n-hexyl benzene (23.7 g, 98.2 mmol) in tetrahydrofuran (20 ml) was added drop wise to magnesium (2.58 g, 106.0 mmol) activated with iodide (5 pellets) such as refluxed was auto-sustained. Mixture was refluxed for 1 hour and cooled down to room temperature. It was diluted with tetrahydrofuran and added drop wise to a suspension of Intermediate 15 (15.0 g, 39.3 mmol) in tetrahydrofuran (225 ml) at 5° C. Mixture was stirred at room temperature overnight. Mixture was cooled down to 0° C. and quenched with hydrochloric acid (1M aqueous, 100 ml). Tetrahydrofuran was removed under reduced pressure and residue was extracted with ethyl acetate (100 ml×2). Combined organic layers were washed with water (100 ml×3), dried over magnesium sulphate and concentrated under reduced pressure. Residue was purified by column chromatography on silica gel using 50% dichloromethane in heptane followed by 50% ethyl acetate in heptane as eluent to yield 10.4 g of Intermediate 17 (38% yield) and 8.3 g of Intermediate 16 (30% yield).

### Intermediate 18:

Trifluoroacetic acid (45 ml, 453.3 mmol) was added to a mixture of Intermediate 16 (9.0 g, 12.7 mmol) and chlorobenzene (45 ml). Solution was stirred at 100° C. for 25 hours and cooled down to room temperature. It was poured into 200 ml of a mixture of ice and water and stirred until mixture reached room temperature. Phases were separated and organic phase was washed with water (×3), dried over magnesium sulphate and concentrated under reduced pressure. Residue was purified by column chromatography on C18 reverse phase silica using a gradient of acetonitrile to 30% tetrahydrofuran in acetonitrile as eluent. Fractions to yield 3.6 g of Intermediate 18 (51% yield).

A mixture of Intermediate 17 (5.0 g, 7.3 mmol), water (25 ml) and concentrated sulfuric acid (25 ml) was stirred for 2.5 days at 160° C. Mixture was cooled down to room temperature and extracted with ethyl acetate. Organic phase was washed with water (×3), dried over magnesium sulphate and concentrated under reduced pressure. Residue was purified by column chromatography on silica gel using 50% dichloromethane in heptane followed by 50% ethyl acetate in heptane as eluent to yield 2.1 g of Intermediate 18 (42% yield).

### Intermediate 19:

Thionyl chloride (1.9 ml, 25.9 mmol) was added drop wise to a solution of Intermediate 18 (8.9 g, 12.9 mmol) in toluene (50 ml). Solution was stirred at 95° C. overnight. Thionyl chloride and toluene were distillated off and residue was dissolved in tetrahydrofuran (10 ml). Ammonia (0.5M in THF, 52 ml, 25.9 mmol) was added drop wise to it at −20° C. Mixture was stirred for 1 hour at room temperature. Extra ammonia (0.5M in THF, 10 ml, 5 mmol) was added and mixture was stirred at room temperature overnight. Water (25 ml) was added to the mixture and tetrahydrofuran was removed under reduced pressure. Residue was extracted with ethyl acetate. Organic phase was washed with water, dried over magnesium sulphate and concentrated under reduced pressure. Residue was purified by filtration through a silica/florisil plug (a layer of florisil packed on top of a layer of silica) using 20% heptane in dichloromethane followed by 40% ethyl acetate in dichloromethane as eluent to yield 6.4 g of Intermediate 19, 85% purity by HPLC, 72% yield.

### Monomer Example 4

Phosphorus pentoxide (2.64 g, 18.6 mmol) was added portion wise to a solution of Intermediate 19 (6.4 g, 9.3 mmol) at room temperature. Mixture was stirred at 110° C. for 4 hours. Mixture was cooled down to room temperature and poured into water (150 ml) at 0° C. It was extracted with ethyl acetate, organic phase was washed with water (×3) dried over magnesium sulphate and concentrated under reduced pressure. Residue was purified by column chromatography using silica gel and a gradient of 5% to 30% ethyl acetate in heptane. Resulting product was stirred with acetonitrile at −30° C. and slurry was left to warm up to room temperature and filtered. Solid was recrystallized from a mixture of toluene and acetonitrile to yield 3.85 g of Monomer Example 4, 99.58% HPLC purity, 62% yield.

¹H-NMR (600 MHz, CDCl3): δ [ppm] 0.87 (t, J=6.9 Hz, 6H), 1.23-1.31 (m, 12H), 1.49-1.55 (m, 4H), 2.52 (m, 4H), 6.83 (d, J=8.0 Hz, 2H), 6.95 (s, 2H), 7.10 (d, J=7.7 Hz, 2H), 7.16 (t, J=7.7 Hz, 2H), 7.52 (d, J=1.8 Hz, 1H), 7.58 (dd, J=1.8, 8.3 Hz, 1H), 7.68 (d, J=1.6 Hz, 1H), 7.74 (d, J=1.7 Hz, 1H), 8.27 (d, J=8.3 Hz, 1H).

### Polymer Example 1

Polymer Example 1 was prepared by Suzuki polymerisation as described in WO 00/53656 of 50 mol % each of the following monomers:

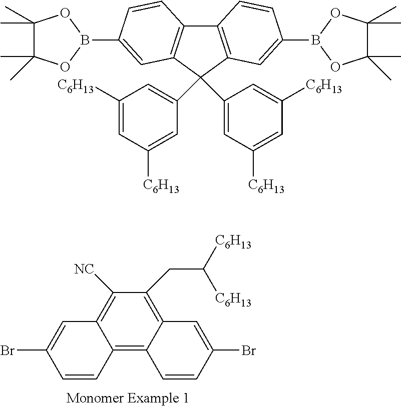

Polymer Example 1 has a Mz of 872,000, a Mw of 547,000, a Mp of 529,000, a Mn of 228,000 a Pd of 2.41.

Polymer Example 1 has a HOMO of 5.97 eV and a LUMO of 2.43 eV.

### Polymer Example 2

Polymer Example 2 was prepared as described for Polymer Example 1 except that the fluorene-containing monomer was replaced with a fluorene-containing monomer as described in WO 2012/104579.

Polymer Example 2 has a Mz of 1,096,000, a Mw of 585,000, a Mp of 574,000, a Mn of 159,000 a Pd of 3.69.

Polymer Example 1 has a HOMO of 5.5 eV and a LUMO of 2.42 eV.

### Polymer Example 3

Polymer Example 3 was prepared as described for Polymer Example 1 using 50 mol % of each of the following monomers:

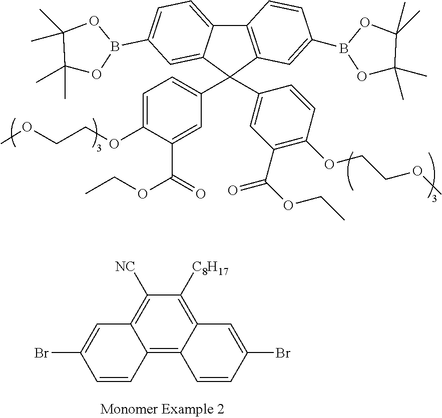

Polymer Example 3 has a Mz of 92,000, a Mw of 53,000, a Mp of 48,000, a Mn of 24,000 a Pd of 2.21.

Polymer Example 1 has a HOMO of −5.91 eV and a LUMO of −2.56 eV.

### Polymer Example 4

Polymer Example 4 was prepared as described for Polymer Example 1 using 50 mol % of each of the following monomers:

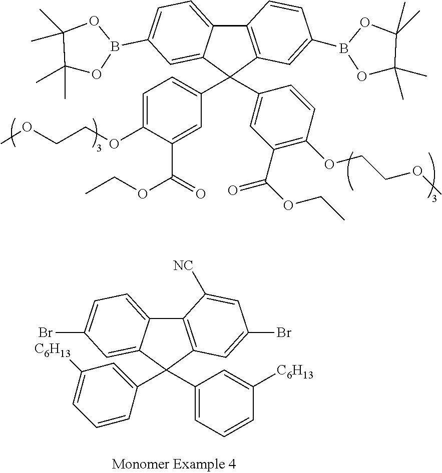

Polymer Example 4 has a Mz of 160,000, a Mw of 91,000, a Mp of 87,000, a Mn of 37,000 a Pd of 2.44.

Polymer Example 4 has a HOMO of −5.91 eV and a LUMO of −2.66 eV.

### Device Example 1

An electron-only device having the layer structure ITO/Polymer+n-dopant (100 nm)/silver (100 nm) was formed on a glass substrate in which the polymer+n-dopant layer was formed by spin-coating an o-xylene solution of Polymer Example 2 (80 wt %) and n-dopant 1 illustrated below (20 wt %) followed by drying at 80° C. in a glove-box. After evaporation of the silver cathode the device was encapsulated using a glass encapsulation can.

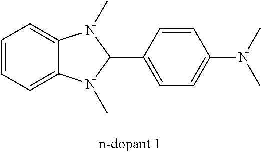 [SMILES: CN(C)c1ccc(C2N(C)c3ccccc3N2C)cc1]

### Device Example 2

A device was formed as described in Device Example 1 except that the device was irradiated with UV light for 10 minutes through the anode following encapsulation.

### Comparative Device 1

A device was prepared as described for Device Example 1 except that n-dopant 1 was not present.

With reference to FIG. 2, current density is very low for Comparative Device 1 as compared to Device Example 1 or 2. The strong increase in current density of Device Example 2 suggests that the extent of doping in Device Example 1 is relatively weak but is greatly increased upon UV treatment as in Device Example 2.

### Device Example 3

Green phosphorescent devices having the following structure were prepared:

ITO (45 nm)/LEL (80 nm)/EIL (20 nm)/Ag (100 nm)
in which ITO is an indium tin oxide anode; LEL is a light-emitting layer; EIL is an electron injection layer and Ag is a silver cathode.

To form the devices, a substrate carrying ITO was cleaned using UV/Ozone. The light-emitting layer was formed by spin-coating an o-xylene composition comprising a crosslinkable blue fluorescent polymer and crosslinking the polymer. The electron-injection layer was formed by spin-coating Polymer Example 2 onto the crosslinked light-emitting layer and spin-coating a formulation of n-dopant 1 (30 wt %) and Electron Transport Polymer 1 (70 wt %) from methanol solution and heating at 80° C. for 10 minutes. The cathode was formed by evaporation of silver.

The blue fluorescent polymer is a conjugated polymer comprising fluorene repeat units and a repeat unit of formula:

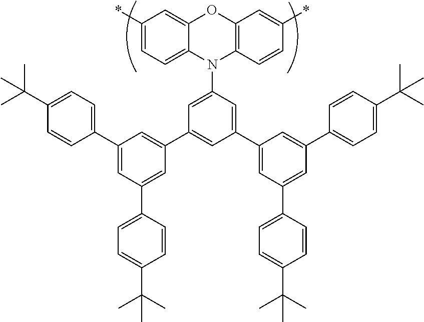

Electron-Transport Polymer 1 is a polymer of the following repeat unit as described in WO 2012/133229, the contents of which are incorporated herein by reference:

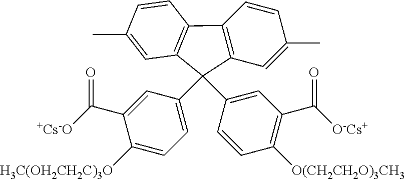

### Device Example 4

A device was prepared as described for Device Example 3 with the additional step of irradiating the device through the glass substrate with blue light having a peak wavelength of 465 nm for 2 hours. using the ENFIS UNO Air Cooled Light Engine available from Enfis Ltd, UK.

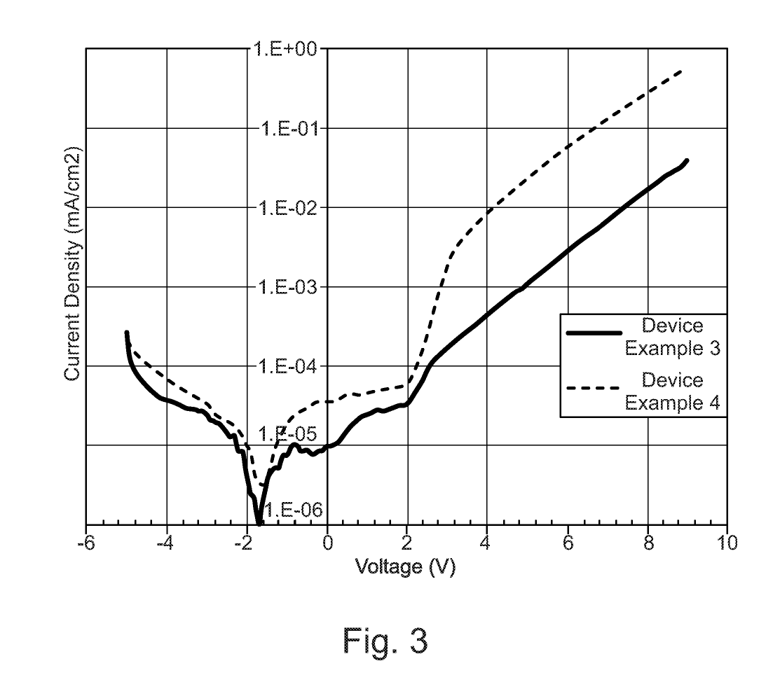

With reference to FIG. 3, an increase in current density of roughly one order of magnitude was observed upon irradiation, indicating that limited spontaneous doping occurred in Device Example 3 and that the extent of doping in Device Example 4 was significantly increased upon irradiation with blue light.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A charge-transfer salt formed from a material comprising a unit of formula (I) and an n-dopant: 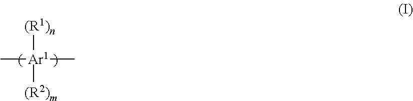
wherein Ar¹ is an arylene group; R¹ is a substituent comprising at least one cyano group; n is at least 1; R² is a substituent; and m is 0 or a positive integer.

2. The charge-transfer salt according to claim 1, wherein Ar¹ is a C₆₋₂₀ arylene group.

3. The charge-transfer salt according to claim 2, wherein Ar¹ is selected from the group consisting of phenylene, fluorene or phenanthrene.

4. The charge-transfer salt according to claim 3, wherein the unit of formula (I) is selected from the group consisting of formulae (Ia)-(Ig): 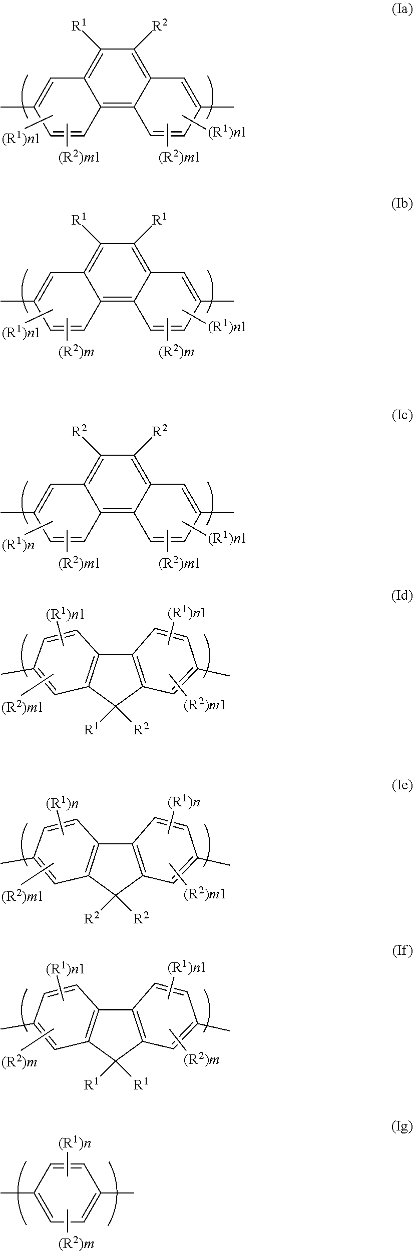
wherein n1 independently in each occurrence is 0 or a positive integer; and ml independently in each occurrence is 0 or a positive integer.

5. The charge-transfer salt according to claim 1, wherein R¹ is cyano.

6. The charge-transfer salt according to claim 1, wherein R¹ is a group of formula (II): 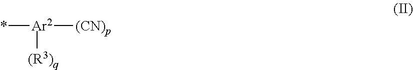
wherein Ar² is any aryl or heteroaryl group; p is at least 1; R³ is a substituent; and q is 0 or a positive integer.

7. The charge-transfer salt according to claim 6, wherein Ar² is phenyl.

8. The charge-transfer salt according to claim 1, wherein the material comprising a unit of formula (I) is a polymer comprising repeat units of formula (I).

9. The charge-transfer salt according to claim 8, wherein the polymer is a copolymer comprising a repeat unit of formula (I) and one or more co-repeat units.

10. The charge-transfer salt according to claim 9, wherein the or each co-repeat unit is a C₆₋₂₀ arylene co-repeat unit which may be unsubstituted or substituted with one or more substituents.

11. The charge-transfer salt according to claim 9, wherein the repeat unit of formula (I) is 0.1-50 mol % of the repeat units of the polymer.

12. The charge-transfer salt according to claim 1, wherein the n-dopant comprises 2,3-dihydro-1H-benzoimidazole.

13. The charge-transfer salt according to claim 1, wherein the material comprising a unit of formula (I): n-dopant weight ratio is in the range 99:1-30:70.

14. A method of forming a charge-transfer salt according to claim 1, comprising the step of activating a composition comprising the material comprising a unit of formula (I) and the n-dopant to cause the n-dopant to dope the material comprising a unit of formula (I).

15. An organic electronic device comprising a layer comprising a charge-transfer salt according to claim 1.

16. The organic electronic device according to claim 15, wherein the organic electronic device is an organic light-emitting device comprising an anode, a cathode and a light-emitting layer between the anode and the cathode and wherein the layer comprising the charge-transfer salt is an electron injection layer between the light-emitting layer and the cathode.

17. The organic electronic device according to claim 16, wherein the electron injection layer is in contact with the light-emitting layer.

18. A composition comprising a material comprising a unit of formula (I) and an n-dopant: 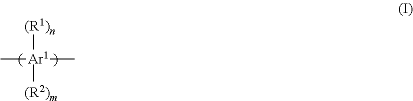
wherein A¹ is an arylene group; R¹ is a substituent comprising at least one cyano group; n is at least 1; R² is a substituent; and m is 0 or a positive integer.

19. A formulation comprising a composition according to claim 18 and at least one solvent.

20. A method of forming a layer of an organic electronic device comprising a charge-transfer salt according to claim 1, the method comprising the step of depositing a formulation according to claim 19 onto a surface; evaporating the at least one solvent; and activating the n-dopant.
